(19) United States
(12) Patent Application Publication
(10) Pub. No.: US 2013/0300456 A1
(43) Pub. Date: Nov. 14, 2013

(54) SEMICONDUCTOR CHIP AND SEMICONDUCTOR DEVICE

(71) Applicant: SEMICONDUCTOR ENERGY LABORATORY CO., LTD., Atsugi-shi (JP)

(72) Inventor: Erwan Lennon, Kanagawa (JP)

(73) Assignee: Semiconductor Energy Laboratory Co., Ltd., Atsugi-shi (JP)

(21) Appl. No.: 13/888,458

(22) Filed: May 7, 2013

(30) Foreign Application Priority Data
May 10, 2012 (JP) 2012-108283

(51) Int. Cl. H03K 19/094

(52) U.S. Cl. CPC H03K 19/094
USPC 326/102

(57) ABSTRACT

Provided is a semiconductor chip for a programmable logic device which can hold configuration data even when supply of a power supply potential is interrupted and can operate with low power. Further, a semiconductor device using the semiconductor chip is provided. The semiconductor chip can hold configuration data even when supply of a power supply potential is interrupted and can operate with low power. The semiconductor chip includes a transistor and a pad connected to the transistor. The transistor is formed using a material which allows a sufficient reduction in off-state current of the transistor; for example, an oxide semiconductor material that is a wide bandgap semiconductor.

### BACKGROUND OF THE INVENTION

1. Field of the Invention

The present invention relates to a semiconductor chip and a semiconductor device including the semiconductor chip.

2. Description of the Related Art

A technology called system in package (SIP) in which different kinds of semiconductor chips are packed in one package is expanding with an increase in size of LSI and complication of the process. By this technology, a semiconductor chip can be combined with another semiconductor chip or a different kind of semiconductor chip, which leads to advance of multifunctionalization. For example, ideas for positions, shapes, and mounting structures of electrodes in the semiconductor chip are proposed (e.g., Patent Document 1).

In addition, a circuit structure of a semiconductor integrated circuit typified by an IC or an LSI is fixed at the time of manufacture and cannot be changed after the manufacture. In contrast, a semiconductor integrated circuit called a programmable logic device (PLD) has a structure in which unit logic blocks each including a plurality of logic circuits are electrically connected to each other through wirings.

In the programmable logic device, a circuit structure of each logic block can be controlled by an electric signal. Thus, the design of the programmable logic device can be changed even after the manufacture and accordingly time and cost required for designing and developing a semiconductor integrated circuit can be greatly reduced with the use of the programmable logic device.

In the programmable logic device, connection of logic blocks is controlled by a programmable switch at an intersection of wirings between the logic blocks, which operates in accordance with data (configuration data) stored in a memory portion. In other words, data is programmed into each programmable switch for controlling connection of wirings between logic blocks, whereby a circuit structure of a programmable logic device can be changed (e.g., Patent Document 2).

### REFERENCE

### [Patent Document]

[Patent Document 1] Japanese Published Patent Application No. 2000-188381
[Patent Document 2] Japanese Published Patent Application No. 2004-312701

### SUMMARY OF THE INVENTION

However, in a programmable logic device including a volatile memory in a memory portion for controlling connection of wirings between logic blocks by programmable switches, when supply of a power supply potential is interrupted, configuration data stored in the memory portion is lost. Thus, configuration data needs to be written to the volatile memory every time the power is restored after having being interrupted. Therefore, there is a long delay time from the start of supply of power to operation of the programmable logic device. In other words, in the programmable logic device including the volatile memory in the memory portion of the programmable switch, it is difficult to perform a normally-off driving method in which supply of a power supply potential is temporarily stopped.

In the case where a non-volatile memory, which has a floating gate transistor (such as a flash memory), is used in a memory portion of a programmable switch controlling connection of wirings between logic blocks, configuration data can be held even when a power supply potential is not supplied temporarily by a normally-off driving method. However, a high potential is needed because electrons are injected into a floating gate in data writing; accordingly, a long time is required to write data.

In addition, when logic blocks including a logic circuit, a programmable switch controlling connection between the logic blocks, and a memory portion of the programmable switch are formed in one semiconductor chip, there is a problem that the manufacturing process become complex.

In view of the above problems, it is an object of the present invention to provide a semiconductor chip for a programmable logic device which can hold configuration data even when supply of a power supply potential is interrupted and can operate with low power. Another object is to provide a semiconductor device using the semiconductor chip.

One embodiment of the disclosed invention is a semiconductor chip for a programmable logic device which can hold configuration data even when supply of a power supply potential is interrupted and can operate with low power. The semiconductor chip includes a transistor and a pad connected to the transistor. The transistor is formed using a material which allows a sufficient reduction in off-state current of the transistor; for example, an oxide semiconductor material that is a wide bandgap semiconductor. When the semiconductor material which allows a sufficient reduction in off-state current of the transistor is used, configuration data can be held even when supply of a power supply potential is interrupted. The semiconductor chip for a programmable logic device can be manufactured independently, and accordingly, the semiconductor chip can be easily combined with another semiconductor chip or a different kind of semiconductor chip. Details are described below.

One embodiment of the present invention is a semiconductor chip for a PLD including a substrate, a transistor over the substrate, the transistor including a gate electrode, a source electrode, and a drain electrode, and an insulating film covering the transistor. The semiconductor chip includes first to third pads on one or both of the top surface and the bottom surface of the semiconductor chip. The first pad is electrically connected to the gate electrode. The second pad is electrically connected to the source electrode. The third pad is electrically connected to the drain electrode.

In the above structure, the semiconductor chip may include through electrode passing through the semiconductor chip and may include a fourth pad connected to one end of the through electrode and a fifth pad connected to the other end of the through electrode.

In the above structure, the transistor preferably includes an oxide semiconductor in a channel formation region.

When the transistor includes an oxide semiconductor which is a wide bandgap semiconductor, off-state current of the transistor can be sufficiently reduced. Thus, configuration data can be held even when supply of a power supply potential is interrupted.

Another embodiment of the present invention is a semiconductor device including a first semiconductor chip in which a logic circuit composed of logic blocks is formed and a second semiconductor chip which is stacked together with and connected to the first semiconductor chip. The second semiconductor chip is the semiconductor chip having the above-described structure.

The first semiconductor chip and the second semiconductor chip can be manufactured independently of each other; thus, the manufacturing process can be simplified. Accordingly, manufacturing cost can be reduced. In addition, since the first semiconductor chip and the second semiconductor chip are stacked and connected to each other, the area of the semiconductor chip can be reduced.

One embodiment of the present invention is preferable when the first semiconductor chip and the second semiconductor chip are formed using different materials. For example, when the first semiconductor chip is formed using a transistor including silicon and the second semiconductor chip is formed using a transistor including an oxide semiconductor, the optimal process for manufacturing the transistor including silicon is different from that of the transistor including an oxide semiconductor.

For example, the transistor including silicon can be formed even with relatively high process temperatures (e.g., 450° C. or higher). Further, in order to recover defects in the silicon, hydrogenation treatment or the like is sometimes needed, for example. On the other hand, the transistor including an oxide semiconductor with favorable electrical characteristics can be formed even with relatively low process temperatures (e.g., lower than 450° C.). However, the hydrogen used for removing defects in the silicon serves as a donor in a film of the oxide semiconductor and thus adversely affects the electrical characteristics of the transistor. Therefore, the first semiconductor chip and the second semiconductor chip are formed independently of each other, so that the transistors can be manufactured by the respective optimal processes and thus can each have the best characteristics.

In the above structure, one or both of the first semiconductor chip and the second semiconductor chip preferably includes a programmable switch controlling connection between the logic blocks.

In the above structure, one or both of the first semiconductor chip and the second semiconductor chip preferably includes a power supply control block controlling a power supply potential of the second semiconductor chip.

Another embodiment of the present invention is a semiconductor device including a first semiconductor chip in which a logic circuit composed of a first logic block is formed, a second semiconductor chip which is stacked together with and connected to the first semiconductor chip, and a third semiconductor chip including a logic circuit composed of a second logic block. The third semiconductor chip is stacked together with and connected to the first semiconductor chip with the second semiconductor chip provided therebetween. The second semiconductor chip is the semiconductor chip having the above-described structure.

The first semiconductor chip, the second semiconductor chip, and the third semiconductor chip can be manufactured independently of one another; thus, the manufacturing process can be simplified. Accordingly, manufacturing cost can be reduced. In addition, since the first semiconductor chip, the second semiconductor chip, and the third semiconductor chip are stacked and connected to one another, the area of the semiconductor chip can be reduced.

In the above structure, at least one of the first semiconductor chip, the second semiconductor chip, and the third semiconductor chip preferably includes a programmable switch controlling connection between the first logic block and the second logic block.

In the above structure, at least one of the first semiconductor chip, the second semiconductor chip, and the third semiconductor chip preferably includes a power supply control switch controlling a power supply potential of the second semiconductor chip.

A semiconductor chip for a programmable logic device which can hold configuration data even when supply of a power supply potential is interrupted and can operate with low power can be provided. In addition, a semiconductor device using the semiconductor chip can be provided.

### BRIEF DESCRIPTION OF THE DRAWINGS

FIGS. 1A to 1C are diagrams each illustrating a semiconductor chip of one embodiment of the present invention.

FIGS. 2A to 2C are diagrams each illustrating a semiconductor chip of one embodiment of the present invention.

FIGS. 3A to 3D are diagrams each illustrating a transistor which can be used for a semiconductor chip of one embodiment of the present invention.

FIGS. 4A to 4D are cross-sectional views illustrating a manufacturing process of a semiconductor chip of one embodiment of the present invention.

FIGS. 5A to 5D are cross-sectional views illustrating a manufacturing process of a semiconductor chip of one embodiment of the present invention.

FIGS. 6A and 6B are block diagrams each illustrating a semiconductor chip of one embodiment of the present invention.

FIGS. 7A and 7B are block diagrams each illustrating a semiconductor chip of one embodiment of the present invention.

FIGS. 8A and 8B are block diagrams each illustrating a semiconductor chip of one embodiment of the present invention.

FIGS. 9A and 9B are diagrams illustrating a semiconductor device of one embodiment of the present invention.

FIG. 10 is a block diagram of a portable electronic device.

FIG. 11 is a block diagram of an e-book reader.

### DETAILED DESCRIPTION OF THE INVENTION

Embodiments of the present invention will be described below with reference to the accompanying drawings. However, the present invention is not limited to the following description and it is easily understood by those skilled in the art that the mode and details can be variously changed without departing from the scope and spirit of the present invention. Therefore, the present invention should not be limited to the descriptions of the embodiments below.

Note that in this specification, functions of the “source” and “drain” may be replaced with each other when a transistor of opposite polarity is employed or when the direction of a current flow changes in a circuit operation, for example. Therefore, the terms “source” and “drain” can be replaced with each other in this specification and the like.

In this specification, the term “electrically connected” includes the case where components are connected through an object having any electric function. There is no particular limitation on the “object having any electric function” as long as electric signals can be transmitted and received between the components connected through the object. Examples of the “object having any electric function” are a switching element such as a transistor, a resistor, an inductor, a capacitor, and an element with a variety of functions as well as an electrode and a wiring.

Note that the position, size, range, or the like of each structure illustrated in drawings and the like is not accurately represented in some cases for easy understanding. Therefore, the disclosed invention is not necessarily limited to the position, size, range, or the like as disclosed in the drawings and the like. Note that in the figures and the like, the same portions or portions having similar functions are denoted by the same reference numerals in common in different drawings and repetitive description thereof will be omitted.

Note that the ordinal numbers such as “first” and “second” in this specification etc., are used for convenience and do not denote the order of steps or the stacking order of layers. In addition, the ordinal numbers in this specification do not denote particular names which specify the present invention. Moreover, these ordinal numbers are used in order to avoid confusion among components, and the terms do not limit the components numerically.

### Embodiment 1

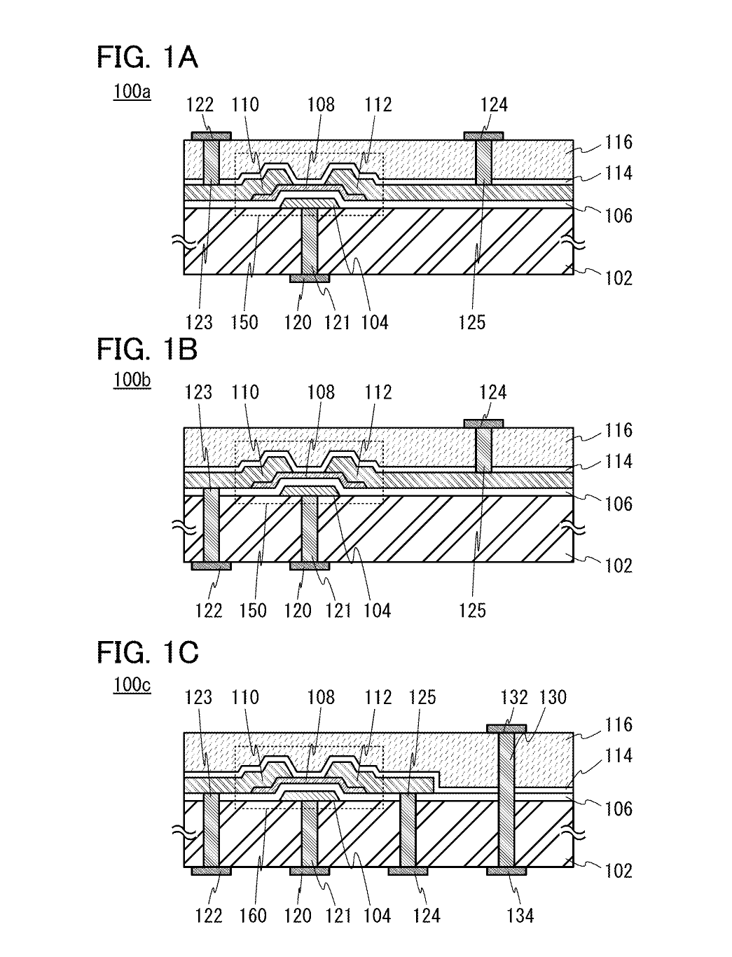

In this embodiment, a semiconductor chip according to one embodiment of the disclosed invention will be described with reference to FIGS. 1A to 1C.

FIG. 1A shows a structure of a semiconductor chip 100a of this embodiment. The semiconductor chip 100a in FIG. 1A, which is used for a programmable logic device, includes a substrate 102, a transistor 150 over the substrate 102 including a gate electrode 104, a source electrode 110, and a drain electrode 112, and insulating films 114 and 116 covering the transistor 150. The semiconductor chip 100a includes a first pad 120 formed on the bottom surface of the semiconductor chip 100a and a second pad 122 and a third pad 124 which are formed on the top surface of the semiconductor chip 100a. The first pad 120 is electrically connected to the gate electrode 104. The second pad 122 is electrically connected to the source electrode 110. The third pad 124 is electrically connected to the drain electrode 112.

Note that in this specification, the top surface and the bottom surface of the semiconductor chip refer to the side where the insulating film covering the transistor is present and the side where the substrate over which the transistor is formed is present, respectively.

FIG. 1B shows a structure of a semiconductor chip 100b of this embodiment. The semiconductor chip 100b in FIG. 1B, which is used for a programmable logic device, includes the substrate 102, the transistor 150 over the substrate 102 including the gate electrode 104, the source electrode 110, and the drain electrode 112, and the insulating films 114 and 116 covering the transistor 150. The semiconductor chip 100b includes the first pad 120 and the second pad 122 formed on the bottom surface of the semiconductor chip 100b and the third pad 124 formed on the top surface of the semiconductor chip 100b. The first pad 120 is electrically connected to the gate electrode 104. The second pad 122 is electrically connected to the source electrode 110. The third pad 124 is electrically connected to the drain electrode 112.

As shown in FIGS. 1A and 1B, the first to third pads may be formed on one or both of the top surface and the bottom surface of the semiconductor chip and can be formed on the suitable surface and at the suitable position by a practitioner as appropriate.

The semiconductor chips 100a and 100b shown in FIGS. 1A and 1B each preferably include a gate insulating film 106 formed over the gate electrode 104, a semiconductor film 108 formed over the gate insulating film 106, a connection electrode 121 connecting the gate electrode 104 and the first pad 120, a connection electrode 123 connecting the source electrode 110 and the second pad 122, and a connection electrode 125 connecting the drain electrode 112 and the third pad 124.

In this manner, the transistor is formed in one semiconductor chip and the first to third pads connected to the transistor are provided; accordingly, the semiconductor chip can be connected to another semiconductor chip or a different kind of semiconductor chip. Therefore, a multifunctional semiconductor chip in which the semiconductor chip of this embodiment is combined with another semiconductor chip or a different kind of semiconductor chip can be provided. In particular, the semiconductor chip of this embodiment is preferably used for a memory portion in a programmable switch of a programmable logic device.

Next, another mode different from the semiconductor chips shown in FIGS. 1A and 1B is described with reference to FIG. 1C.

FIG. 1C shows a structure of a semiconductor chip 100c of this embodiment. The semiconductor chip 100c in FIG. 1C, which is used for a programmable logic device, includes the substrate 102, a transistor 160 over the substrate 102 including the gate electrode 104, the source electrode 110, and the drain electrode 112, and the insulating films 114 and 116 covering the transistor 160. The semiconductor chip 100c includes the first pad 120, the second pad 122, and the third pad 124 formed on the bottom surface of the semiconductor chip 100c. The first pad 120 is electrically connected to the gate electrode 104. The second pad 122 is electrically connected to the source electrode 110. The third pad 124 is electrically connected to the drain electrode 112. The semiconductor chip 100c includes a through electrode 130 passing through the semiconductor chip 100c, a fourth pad 132 connected to one end of the through electrode 130, and a fifth pad 134 connected to the other end of the through electrode 130.

The semiconductor chip 100c shown in FIG. 1C preferably includes the gate insulating film 106 formed over the gate electrode 104, the semiconductor film 108 formed over the gate insulating film 106, the connection electrode 121 connecting the gate electrode 104 and the first pad 120, the connection electrode 123 connecting the source electrode 110 and the second pad 122, and the connection electrode 125 connecting the drain electrode 112 and the third pad 124.

With the structure of the semiconductor chip 100c shown in FIG. 1C, a plurality of semiconductor chips can be connected with the semiconductor chip 100c provided therebetween with the fourth pad 132 and the fifth pad 134.

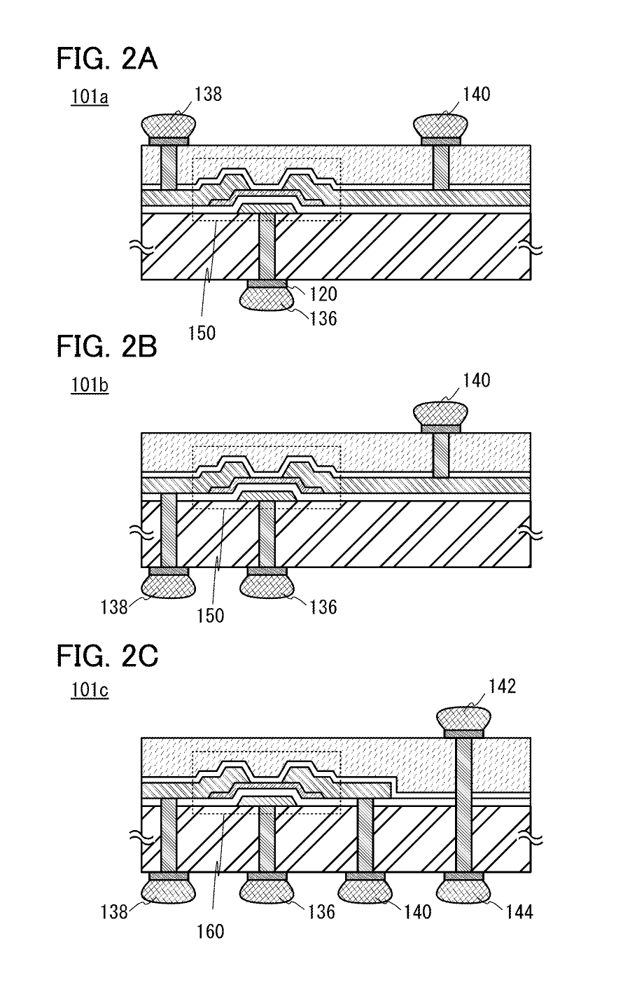

The semiconductor chips 100a, 100b, and 100c in FIGS. 1A to 1C may include a solder bump on each pad. FIGS. 2A to 2C shows structures in which the semiconductor chips in FIGS. 1A to 1C each include the solder bump.

A semiconductor chip 101a shown in FIG. 2A includes solder bumps 136, 138, and 140 on respective pads of the semiconductor chip 100a shown in FIG. 1A. A semiconductor chip 101b shown in FIG. 2B includes the solder bumps 136, 138, and 140 on respective pads of the semiconductor chip 100b shown in FIG. 1B. A semiconductor chip 101c shown in FIG. 2C includes the solder bumps 136, 138, and 140 and solder bumps 142 and 144 on respective pads of the semiconductor chip 100c shown in FIG. 1C. These structures are preferable for connection with another semiconductor chip or a different kind of semiconductor chip.

Here, a transistor with extremely low off-state current is used as each of the transistors 150 and 160 shown in FIGS. 1A to 1C. For example, a wide bandgap semiconductor such as an oxide semiconductor is used for the semiconductor film 108. With the use of such a transistor with extremely low off-state current as each of the transistors 150 and 160, when the transistors 150 and 160 are off, potentials of the second pad 122 and the third pad 124 which are respectively connected to the source electrode 110 and the drain electrode 112 can be held for a very long period. In other words, external potentials connected to the second pad 122 and the third pad 124 can be held for a very long period. Therefore, the semiconductor chips 100a to 100c including the transistors 150 and 160 can be used for a memory portion in a programmable switch of a programmable logic device.

In this specification, the semiconductor chips shown in FIGS. 1A to 1C are used particularly for a memory portion in a programmable switch of a programmable logic device as an example; however, the present invention is not limited to this example. As described above, since the semiconductor chip of one embodiment of the present invention can hold the external potentials connected to the second pad 122 and the third pad 124 for a very long period, the semiconductor chip can be also used for a memory portion of a switch controlling connection of a power supply potential, a switch controlling connection of an analog sensor, a switch controlling connection of a register, a switch controlling a connection of a capacitor, and the like in a programmable logic device.

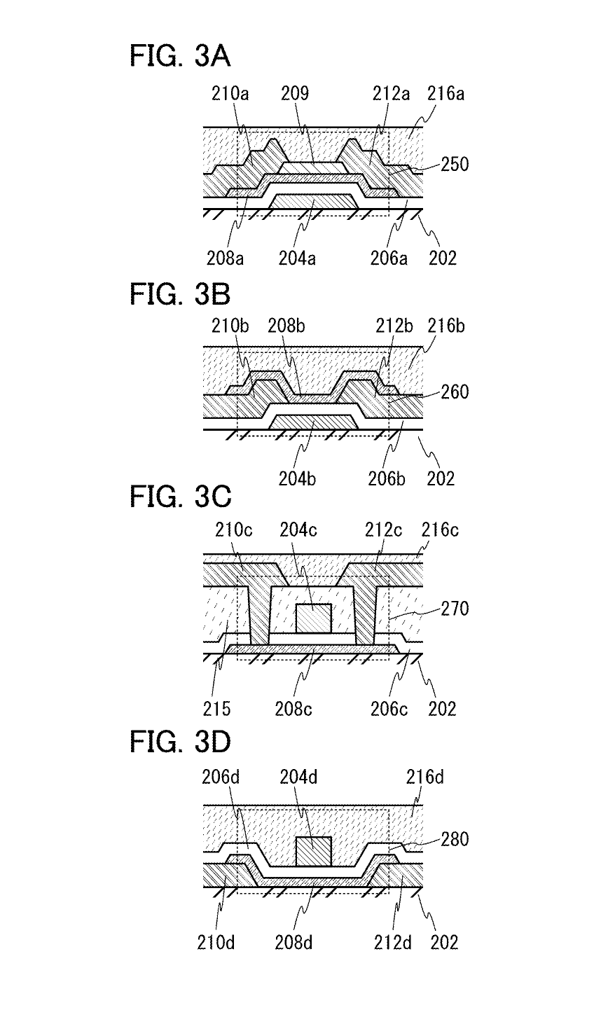

Although a bottom-gate (an inverted staggered) transistor is used in the above description as each of the transistors 150 and 160 shown in FIGS. 1A to 1C, the structures of the transistors are not limited to the example. For example, the structures of the transistors shown in FIGS. 3A to 3D can be applied.

A transistor 250 shown in FIG. 3A includes a gate electrode 204a formed over a substrate 202, a gate insulating film 206a formed over the gate electrode 204a, a semiconductor film 208a formed over the gate insulating film 206a, a channel protective film 209 formed over the semiconductor film 208a, and a source electrode 210a and a drain electrode 212a formed over the gate insulating film 206a, the semiconductor film 208a, and the channel protective film 209. An insulating film 216a covering the transistor 250 may be included.

The transistor 250 is different from the transistors 150 and 160 in that the channel protective film 209 is formed. It is preferable to provide the channel protective film 209 because damage to the semiconductor film 208a can be suppressed during processing for forming the source electrode 210a and the drain electrode 212b.

A transistor 260 shown in FIG. 3B includes a gate electrode 204b formed over the substrate 202, a gate insulating film 206b formed over the gate electrode 204b, a source electrode 210b and a drain electrode 212b formed over the gate insulating film 206b, and a semiconductor film 208b formed over the gate insulating film 206b, the source electrode 210b, and the drain electrode 212b. An insulating film 216b covering the transistor 260 may be included.

The positions of the source electrode 210b and the drain electrode 212b to the semiconductor film 208b in the transistor 260 are different from those in the transistors 150 and 160. As in the transistor 260, the source electrode 210b and the drain electrode 212b may be in contact with the bottom surface of the semiconductor film 208b.

A transistor 270 shown in FIG. 3C includes a semiconductor film 208c formed over the substrate 202, a gate insulating film 206c formed over the substrate 202 and the semiconductor film 208c, a gate electrode 204c formed over the gate insulating film 206c, an interlayer insulating film 215 formed over the gate insulating film 206c and the gate electrode 204c, and a source electrode 210c and a drain electrode 212c electrically connected to the semiconductor film 208c through openings which are provided in the gate insulating film 206c and the interlayer insulating film 215. An insulating film 216c covering the transistor 270 may be included.

The position of the gate electrode 204c to the semiconductor film 208c in the transistor 270 is different from those in the transistors 150 and 160, i.e., the transistor 270 is a so-called top-gate transistor. The top-gate transistor is suitable for miniaturization of the transistor. Further, the semiconductor film 208c in FIG. 3C may have different resistances by introducing impurities to the semiconductor film 208c using the gate electrode 204c as a mask (this case is not shown). A sidewall insulating film or the like may be formed on the side surface of the gate electrode 204c.

A transistor 280 shown in FIG. 3D includes a source electrode 210d and a drain electrode 212d formed over the substrate 202; a semiconductor film 208d formed over the substrate 202, the source electrode 210d, and the drain electrode 212d; a gate insulating film 206d formed over the semiconductor film 208d, the source electrode 210d, and the drain electrode 212d; and a gate electrode 204d formed over the gate insulating film 206d. An insulating film 216d covering the transistor 280 may be included.

The position of the gate electrode 204d to the semiconductor film 208d in the transistor 280 is different from that in the transistors 150 and 160, i.e., the transistor 280 is a so-called top-gate transistor. The position of the source electrode 210d and the drain electrode 212d to the semiconductor film 208d in the transistor 280 is different from that in the transistors 270 shown in FIG. 3C.

As shown in FIGS. 3A to 3D, the most suitable structure of the transistor used for the semiconductor chip of this embodiment can be determined by a practitioner as appropriate. Although the insulating films 216a, 216b, 216c, and 216d are each illustrated as a single layer in FIGS. 3A to 3D, a stacked-layer of two or more different insulating films may be used as needed.

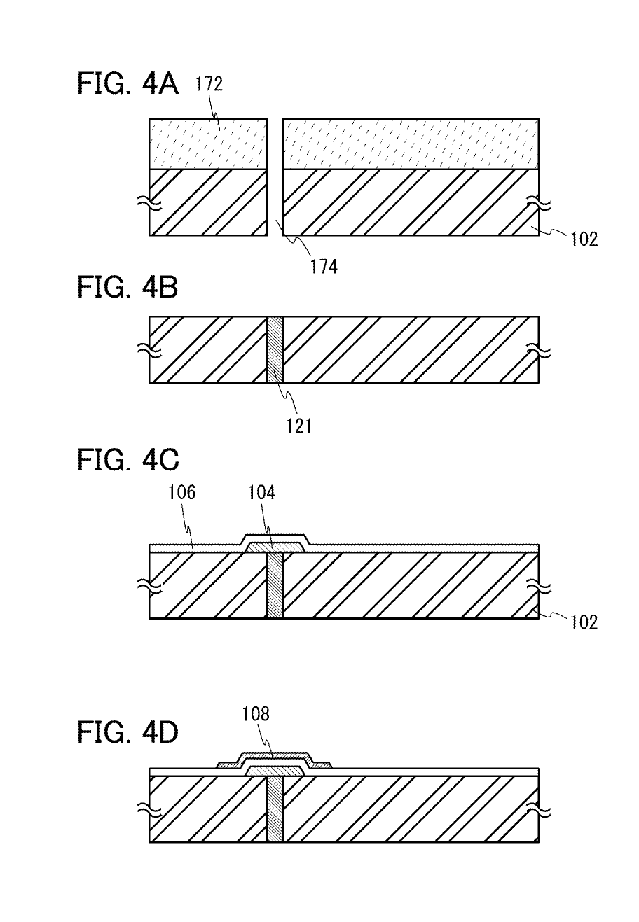

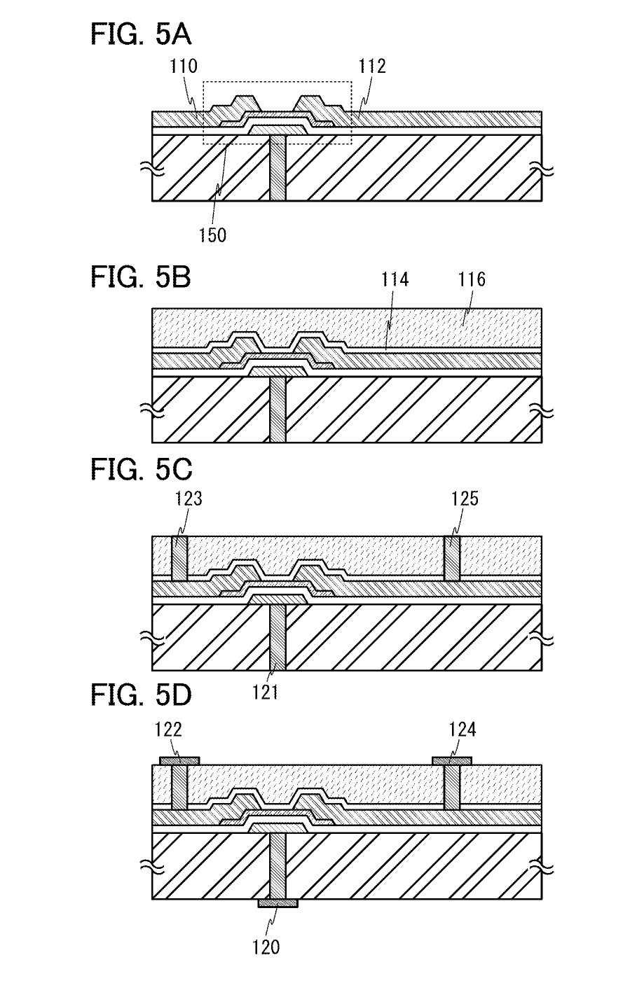

Next, a method for manufacturing the semiconductor chip 100a shown in FIG. 1A is described with reference to FIGS. 4A to 4D and FIGS. 5A to 5D.

First, the substrate 102 is prepared. Then, a resist mask 172 is formed over the substrate 102 and etching is performed using the resist mask 172 as a mask, whereby a through hole 174 is formed (see FIG. 4A).

Although there is no particular limitation on a substrate that can be used as the substrate 102, it is necessary that the substrate have heat resistance to withstand at least heat treatment performed later. For example, a glass substrate of barium borosilicate glass, aluminoborosilicate glass, or the like, a ceramic substrate, a quartz substrate, or a sapphire substrate can be used. Alternatively, a single-crystal semiconductor substrate of silicon, silicon carbide, or the like, a polycrystalline semiconductor substrate, a compound semiconductor substrate of silicon germanium or the like, an SOI substrate, or the like can be used. Alternatively, a flexible substrate may be used as the substrate 102.

In the case where the substrate 102 is a conductive substrate (e.g., a Si wafer or the like), an insulating film or the like may be formed in the through hole 174. Alternatively, one or more films selected from films containing any of a silicon oxide, a silicon nitride, a silicon oxynitride, a silicon nitride oxide, an aluminum oxide, an aluminum nitride, an aluminum oxynitride, an aluminum nitride oxide, and a mixed material of any of these may be formed as a base insulating film over the substrate 102.

Next, the connection electrode 121 is formed in the through hole 174 (see FIG. 4B).

In order to form the connection electrode 121, a conductive material such as conductive paste typified by silver, copper, and the like may be applied into the through hole 174; or the conductive material may be formed on the substrate 102 and in the through hole 174 by a sputtering method or the like, and then, the conductive material in an unnecessary region is removed by a chemical mechanical polishing (CMP) treatment. The connection electrode 121 may be formed as follows: tungsten silicide is formed from WF₆ gas and SiH₄ gas by a CVD method as the conductive material of the connection electrode 121, and the opening is filled with a conductive film formed of the tungsten silicide.

Next, a conductive film is formed over the substrate 102 and the connection electrode 121 and is selectively etched, whereby the gate electrode 104 is formed. After that, the gate insulating film 106 is formed over the substrate 102 and the gate electrode 104 (see FIG. 4C).

As the gate electrode 104, for example, a metal material such as molybdenum, titanium, tantalum, tungsten, aluminum, copper, neodymium, or scandium, or an alloy material including any of these materials as a main component can be used. Alternatively, the conductive film used for the gate electrode may be formed using a conductive metal oxide. As the conductive metal oxide, an indium oxide (In₂O₃), a tin oxide (SnO₂), a zinc oxide (ZnO), an indium tin oxide (In₂O₃—SnO₂, which is abbreviated to ITO in some cases), an indium zinc oxide (In₂O₃—ZnO), or any of these metal oxide materials in which silicon or a silicon oxide is included can be used. The conductive film to be the gate electrode 104 can be formed to have a single layer or a stacked structure using any of the above materials. There is no particular limitation on the formation method, and a variety of film formation methods such as an evaporation method, a PE-CVD method, a sputtering method, and a spin coating method can be employed.

The gate insulating film 106 can be formed using a silicon oxide, a gallium oxide, an aluminum oxide, a silicon nitride, a silicon oxynitride, an aluminum oxynitride, a silicon nitride oxide, or the like. In the case where the semiconductor film 108 formed later is the oxide semiconductor film, the gate insulating film 106 is preferably an insulating film in which a portion in contact with the semiconductor film 108 contains excess oxygen. In particular, the gate insulating film 106 preferably contains oxygen at an amount which exceeds at least the stoichiometric composition. For example, in the case where a silicon oxide film is used as the gate insulating film 106, a film of SiO_{2+α} (α>0) is preferably used. In this embodiment, a silicon oxide film of SiO_{2+α} (α>0) is used as the gate insulating film 106. With the use of the silicon oxide film as the gate insulating film 106, oxygen can be supplied to the oxide semiconductor film used as the semiconductor film 108 and excellent electric characteristics can be obtained.

Further, the gate insulating film 106 can have a thickness greater than or equal to 1 nm and less than or equal to 500 nm. There is no particular limitation on a method of forming the gate insulating film 106; for example, a sputtering method, an MBE method, a PE-CVD method, a pulsed laser deposition method, an ALD method, or the like can be used as appropriate.

Next, a semiconductor film is formed over the gate insulating film 106 and is selectively etched, whereby the semiconductor film 108 is formed (see FIG. 4D).

The semiconductor film 108 is formed using a material which allows a sufficient reduction in off-state current; for example, an oxide semiconductor material which is a wide bandgap semiconductor having a wider bandgap and lower intrinsic carrier density than silicon. For example, as such a wide bandgap semiconductor, a compound semiconductor such as silicon carbide (SiC) or gallium nitride (GaN), an oxide semiconductor formed of a metal oxide such as an In—Ga—Zn-based oxide semiconductor, or the like can be used.

The oxide semiconductor film used as the semiconductor film 108 may have either a single-layer structure or a stacked-layer structure. Further, the oxide semiconductor layer may either have an amorphous structure or a crystalline structure. In the case where the oxide semiconductor film has an amorphous structure, heat treatment may be performed on the oxide semiconductor film in a later manufacturing step so that the oxide semiconductor film has crystallinity. The heat treatment for crystallizing the amorphous oxide semiconductor film is performed at a temperature higher than or equal to 250° C. and lower than or equal to 700° C., preferably higher than or equal to 400° C., further preferably higher than or equal to 500° C., still further preferably higher than or equal to 550° C. Note that the heat treatment can also serve as another heat treatment in the manufacturing process.

In this embodiment, as the semiconductor film 108, an In—Ga—Zn-based oxide (IGZO) film with a thickness of 20 nm is used.

The oxide semiconductor film can be formed by a sputtering method, a molecular beam epitaxy (MBE) method, a plasma CVD method, a pulse laser deposition method, an atomic layer deposition (ALD) method, or the like as appropriate.

In the formation of the oxide semiconductor film, the hydrogen concentration in the oxide semiconductor film is preferably reduced as much as possible. In order to reduce the hydrogen concentration, for example, in the case where the oxide semiconductor layer is formed by a sputtering method, a high-purity rare gas (typically argon), high-purity oxygen, or a high-purity mixed gas of a rare gas and oxygen, from which impurities such as hydrogen, water, a hydroxyl group, and hydride have been removed, is used as appropriate as an atmosphere gas supplied to a process chamber of a sputtering apparatus.

The oxide semiconductor film is formed in such a manner that a sputtering gas from which hydrogen and water have been removed is introduced into the deposition chamber while moisture remaining in the deposition chamber is removed, whereby the hydrogen concentration in the formed oxide semiconductor film can be reduced. In order to remove the residual moisture in the deposition chamber, an entrapment vacuum pump, for example, a cryopump, an ion pump, or a titanium sublimation pump is preferably used. The evacuation unit may be a turbo molecular pump provided with a cold trap. When the deposition chamber is evacuated with the cryopump, which has a high capability in removing a hydrogen molecule, a compound containing a hydrogen atom such as water (H₂O) (more preferably, also a compound containing a carbon atom), and the like, the impurity concentration in the oxide semiconductor film formed in the deposition chamber can be reduced.

In this embodiment, the oxide semiconductor film is formed by a sputtering method using a metal oxide target having an atomic ratio of In:Ga:Zn=1:1:1. Note that the target that can be used for forming the oxide semiconductor film is not limited to the target including the above materials with the above ratios. The oxide semiconductor film can be formed by a sputtering method in a rare gas (typically argon) atmosphere, an oxygen atmosphere, or a mixed atmosphere of a rare gas and oxygen.

Further, the target that can be used for forming the oxide semiconductor film preferably has crystallinity; that is, a single crystalline target, a polycrystalline target, or the like are preferably used. With the use of the target having crystallinity, formed thin films also have crystallinity; specifically, the formed thin films tend to have a c-axis-aligned crystal.

The oxide semiconductor film is preferably in a supersaturated state in which oxygen which exceeds the stoichiometric composition is contained just after its formation. For example, when an oxide semiconductor film is formed by a sputtering method, it is preferable that the film be formed in a film formation gas containing a high percentage of oxygen, and it is especially preferable that the film be formed under an oxygen atmosphere (oxygen gas 100%). For example, when the oxide semiconductor film is formed using an In—Ga—Zn-based oxide (IGZO) under a condition that the proportion of oxygen in the deposition gas is large (in particular, oxygen gas: 100%), release of Zn from the film can be reduced even when the deposition temperature is 300° C. or higher.

Further, when the oxide semiconductor film is formed using the above metal oxide target with the atomic ratio of In:Ga:Zn=1:1:1, the composition of the target is different from the composition of a thin film formed over the substrate in some cases. For example, when the metal oxide target with the atomic ratio of In:Ga:Zn=1:1:1 is used, the composition ratio of the oxide semiconductor film, which is the thin film, becomes In:Ga:Zn=1:1:0.6 to 1:1:0.8 in an atomic ratio in some cases, though it depends on the film formation conditions. This is because in deposition of the oxide semiconductor film, Zn is sublimed, or because a sputtering rate differs between the components of In, Ga, and Zn.

Accordingly, when a thin film having a preferable composition ratio is formed, a composition ratio of the metal oxide target needs to be adjusted in advance. For example, in order to make the composition ratio of the thin oxide semiconductor film be In:Ga:Zn=1:1:1 in an atomic ratio, the composition ratio of the metal oxide target is made to be In:Ga:Zn=1:1:1.5 in an atomic ratio. In other words, the percentage of Zn content in the metal oxide target is preferably made higher in advance. The composition ratio of the target is not limited to the above value, and can be adjusted as appropriate depending on the film formation conditions or the composition of the thin film to be formed. Further, it is preferable to increase the percentage of Zn content in the metal oxide target because in that case, the obtained thin film can have higher crystallinity.

Further, in the case where the oxide semiconductor film is formed by a sputtering method, the relative density of the metal oxide target which is used for forming the oxide semiconductor film is greater than or equal to 90% and less than or equal to 100%, preferably greater than or equal to 95%, more preferably greater than or equal to 99.9%. This is because, with the use of the oxide target with a high relative density, the formed oxide semiconductor film can be a dense film.

An oxide semiconductor used for the oxide semiconductor film preferably contains at least indium (In) or zinc (Zn). In particular, both In and Zn are preferably contained. As a stabilizer for reducing variation in electric characteristics of a transistor using the oxide semiconductor, gallium (Ga) is preferably additionally contained. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

As another stabilizer, one or plural kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) may be contained.

As the oxide semiconductor, for example, an indium oxide, a tin oxide, a zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that here, for example, an “In—Ga—Zn-based oxide” means an oxide containing In, Ga, and Zn as its main components and there is no limitation on the ratio of In:Ga:Zn. The In—Ga—Zn-based oxide may contain a metal element other than the In, Ga, and Zn.

Alternatively, a material represented by InMO₃(ZnO)ₘ, (m>0 is satisfied, and m is not an integer) may be used as an oxide semiconductor. Note that M represents one or more metal elements selected from Ga, Fe, Mn, and Co. Alternatively, as the oxide semiconductor, a material expressed by a chemical formula, In₂SnO₅(ZnO)ₙ (n>0, n is a natural number) may be used.

For example, it is possible to use an In—Ga—Zn-based oxide with an atomic ratio of In:Ga:Zn=1:1:1, In:Ga:Zn=2:2:1, or In:Ga:Zn=3:1:2, or any of oxides whose composition is in the neighborhood of the above compositions. Alternatively, an In—Sn—Zn-based oxide with an atomic ratio of In:Sn:Zn=1:1:1, In:Sn:Zn=2:1:3, or In:Sn:Zn=2:1:5, or any of oxides whose composition is in the neighborhood of the above compositions may be used.

However, without limitation to the materials given above, a material with an appropriate composition may be used depending on needed electrical characteristics (e.g., mobility, threshold voltage, and variation). In order to obtain the needed semiconductor characteristics, the carrier concentration, the impurity concentration, the defect density, the atomic ratio between a metal element and oxygen, the interatomic distance, the density, and the like are preferably set to appropriate values.

For example, with an In—Sn—Zn-based oxide, high mobility can be realized relatively easily. However, mobility can be increased by reducing the defect density in a bulk also in the case of using an In—Ga—Zn-based oxide.

Note that for example, the expression “the composition of an oxide including In, Ga, and Zn at the atomic ratio, In:Ga:Zn=a:b:c (a+b+c=1), is in the neighborhood of the composition of an oxide containing In, Ga, and Zn at the atomic ratio, In:Ga:Zn=A:B:C (A+B+C=1)” means that a, b, and c satisfy the following relation: (a−A)²+(b−B)²+(c−C)²≦r², and r may be 0.05, for example. The same applies to other oxides.

The oxide semiconductor film is preferably a c-axis aligned crystalline oxide semiconductor (CAAC-OS) film.

The oxide semiconductor film may include a non-single-crystal part, for example. The non-single-crystal state is, for example, structured by at least one of c-axis aligned crystal (CAAC), polycrystal, microcrystal, and an amorphous part.

In an image obtained with a transmission electron microscope (TEM), for example, crystal parts can be found in the CAAC-OS in some cases. Note that in most cases, a crystal part in the CAAC-OS fits inside a cube whose one side is 100 nm in an image obtained with the TEM, for example. In an image obtained with a TEM, a boundary between the crystal parts in the CAAC-OS is not clearly observed in some cases. Further, in an image obtained with a TEM, a grain boundary in the CAAC-OS is not clearly observed in some cases. In the CAAC-OS, since a clear grain boundary does not exist, for example, segregation of an impurity is unlikely to occur. In the CAAC-OS, since a clear boundary does not exist, for example, high density of defect states is unlikely to occur. In the CAAC-OS, since a clear grain boundary does not exist, for example, a reduction in electron mobility is unlikely to occur.

For example, the CAAC-OS includes a plurality of crystal parts. In the plurality of crystal parts, c-axes are aligned in a direction parallel to a normal vector of a surface where the CAAC-OS is formed or a normal vector of a surface of the CAAC-OS in some cases. When the CAAC-OS is analyzed by an out-of-plane method with an X-ray diffraction (XRD) apparatus, a peak at 2θ of around 31 degrees which shows alignment appears in some cases. Further, for example, spots (luminescent spots) are shown in an electron diffraction image of the CAAC-OS in some cases. An electron diffraction image obtained with an electron beam having a beam diameter of 10 nm or smaller, or 5 nm or smaller, is called a nanobeam electron diffraction image. In the CAAC-OS, for example, among crystal parts, the directions of the a-axis and the b-axis of one crystal part are different from those of another crystal part, in some cases. In the CAAC-OS, for example, c-axes are aligned, and a-axes and/or b-axes are not macroscopically aligned, in some cases.

In each of the crystal parts included in the CAAC-OS, for example, a c-axis is aligned in a direction parallel to a normal vector of a surface where the CAAC-OS is formed or a normal vector of a surface of the CAAC-OS. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5°.

Further, the CAAC-OS can be formed by reducing the density of defect states for example. In an oxide semiconductor, for example, oxygen vacancies cause an increase in the density of defect states. The oxygen vacancies serve as carrier traps or serve as carrier generation sources when hydrogen is captured therein. In order to form the CAAC-OS, for example, it is important to prevent oxygen vacancies from being generated in the oxide semiconductor. Thus, the CAAC-OS is an oxide semiconductor having a low density of defect states. In other words, the CAAC-OS is an oxide semiconductor having few oxygen vacancies.

The state in which impurity concentration is low and density of defect states is low (the number of oxygen vacancies is small) is referred to as “highly purified intrinsic” or “substantially highly purified intrinsic”. A highly purified intrinsic or substantially highly purified intrinsic oxide semiconductor has few carrier generation sources, and thus has a low carrier density in some cases. Thus, in some cases, a transistor including the oxide semiconductor in a channel formation region rarely has a negative threshold voltage (is rarely normally-on). A highly purified intrinsic or substantially highly purified intrinsic oxide semiconductor has a low density of defect states and accordingly has few carrier traps in some cases. Thus, the transistor including the oxide semiconductor in the channel formation region has a small variation in electrical characteristics and high reliability in some cases. An electric charge trapped by the carrier traps in the oxide semiconductor takes a long time to be released. The trapped electric charge may behave like a fixed electric charge. Thus, the transistor which includes the oxide semiconductor having a high density of defect states in the channel formation region has unstable electrical characteristics in some cases.

With the use of the high purified intrinsic or substantially highly purified intrinsic CAAC-OS in a transistor, variation in the electrical characteristics of the transistor due to irradiation with visible light or ultraviolet light is small.

The oxide semiconductor film may include polycrystal, for example. Note that an oxide semiconductor including polycrystal is referred to as a polycrystalline oxide semiconductor. A polycrystalline oxide semiconductor includes a plurality of crystal grains. A polycrystalline oxide semiconductor includes, for example, amorphous parts in some cases.

For example, the oxide semiconductor film may include microcrystal. Note that an oxide semiconductor including microcrystal is referred to as a microcrystalline oxide semiconductor. A microcrystalline oxide semiconductor is not absolutely amorphous.

In an image obtained with the TEM, for example, crystal parts cannot be found clearly in the microcrystalline oxide semiconductor in some cases. In most cases, a crystal part in the microcrystalline oxide semiconductor is greater than or equal to 1 nm and less than or equal to 100 nm, or greater than or equal to 1 nm and less than or equal to 10 nm, for example. A microcrystal with a size greater than or equal to 1 nm and less than or equal to 10 nm is specifically referred to as nanocrystal (nc), for example. An oxide semiconductor including nanocrystal is referred to as an nc-OS (nanocrystalline oxide semiconductor). In an image of the nc-OS obtained with the TEM, a boundary between crystal parts is not clearly detected in some cases. In the nc-OS which does not have a clear boundary, for example, segregation of an impurity, an increase in the density of defect states, and a reduction in electron mobility hardly occur.

In the nc-OS, for example, a microscopic region (for example, a region with a size greater than or equal to 1 nm and less than or equal to 10 nm) has a periodic atomic order occasionally. Further, for example, in the nc-OS, crystal parts are not regularly-arranged. Thus, there is a case where periodic atomic order is not observed microscopically or a case where long-range order in atomic arrangement is not observed. Accordingly, in some cases, the nc-OS cannot be distinguished from an amorphous oxide semiconductor, for example, depending on an analysis method. When the nc-OS film is analyzed by an out-of-plane method with an XRD apparatus using an X-ray having a beam diameter larger than that of a crystal part, a peak which shows alignment does not appear in some cases. Further, for example, a halo pattern is shown in some cases in an electron diffraction image of the nc-OS obtained by using an electron beam having a beam diameter larger than that of a crystal part (for example, a beam diameter of 20 nmφ or more, or 50 nmφ more). For example, spots are shown in some cases in a nanobeam electron diffraction image of the nc-OS obtained by using an electron beam having a beam diameter smaller than or equal to that of a crystal part (for example, a beam diameter of 10 nmφ or less, or 5 nmφ or less). In a nanobeam electron diffraction image of the nc-OS, for example, regions with high luminance in a circular pattern are shown in some cases. In a nanobeam electron diffraction image of the nc-OS, for example, a plurality of spots is shown in the region in some cases.

Since the microscopic region in the nc-OS has a periodic atomic order occasionally, the nc-OS has lower density of defect states than the amorphous oxide semiconductor. Note that since crystal parts in the nc-OS are not regularly-arranged, the nc-OS has higher density of defect states than the CAAC-OS.

Note that the oxide semiconductor film may be a mixed film including two or more of a CAAC-OS, a polycrystalline oxide semiconductor, a microcrystalline oxide semiconductor, and an amorphous oxide semiconductor. The mixed film includes two or more of an amorphous oxide semiconductor region, a microcrystalline oxide semiconductor region, a polycrystalline oxide semiconductor region, and a CAAC-OS region in some cases. The mixed film has a stacked-layer structure of two or more of an amorphous oxide semiconductor region, a microcrystalline oxide semiconductor region, a polycrystalline oxide semiconductor region, and a CAAC-OS region in some cases.

There are three methods for obtaining a CAAC-OS film when the CAAC-OS film is used as the oxide semiconductor film. The first method is to form an oxide semiconductor layer at a film formation temperature higher than or equal to 100° C. and lower than or equal to 450° C., more preferably higher than or equal to 150° C. and lower than or equal to 400° C., thereby obtaining c-axis alignment substantially perpendicular to a surface. The second method is to form a thin oxide semiconductor film and then subject the film to heat treatment performed at a temperature higher than or equal to 200° C. and lower than or equal to 700° C., thereby obtaining c-axis alignment substantially perpendicular to a surface. The third method is to form a first thin oxide semiconductor film, subject the film to heat treatment performed at a temperature higher than or equal to 200° C. and lower than or equal to 700° C., and then form a second oxide semiconductor film, thereby obtaining c-axis alignment substantially perpendicular to a surface.

Note that when a crystalline (single-crystal or microcrystalline) oxide semiconductor film other than a CAAC-OS film is formed as the oxide semiconductor film, the film formation temperature and the temperature of heat treatment are not particularly limited.

The energy gap of the oxide semiconductor film disclosed in this specification and the like is 2.8 eV to 3.2 eV, which is greater than that of silicon (1.1 eV). Further, the intrinsic carrier density of the oxide semiconductor film is 10⁻⁹/cm³, which is extremely smaller than that of silicon, 10¹¹/cm³.

Majority carriers (electrons) of the oxide semiconductor film flow only from a source of a transistor. Further, a channel formation region can be depleted completely. Thus, an off-state current of the transistor can be extremely small. The off-state current of the transistor including the oxide semiconductor film is as small as 10 yA/μm or less at room temperature, or 1 zA/μm or less between 85° C. and 95° C.

Note that the oxide semiconductor film may have a structure in which a plurality of oxide semiconductor films is stacked. For example, the oxide semiconductor film may have a stacked-layer structure of a first oxide semiconductor layer and a second oxide semiconductor layer which are formed using metal oxides with different compositions. For example, the first oxide semiconductor layer may be formed using a three-component metal oxide, and the second oxide semiconductor layer may be formed using a two-component metal oxide. Alternatively, for example, both the first oxide semiconductor layer and the second oxide semiconductor layer may be formed using three-component metal oxides.

Further, the constituent elements of the first oxide semiconductor layer and the second oxide semiconductor layer are made to be the same and the composition ratio of the constituent elements of the first oxide semiconductor layer and the second oxide semiconductor layer may be made to be different. For example, the first oxide semiconductor layer may have an atomic ratio of In:Ga:Zn=1:1:1 and the second oxide semiconductor layer may have an atomic ratio of In:Ga:Zn=3:1:2. Alternatively, the first oxide semiconductor layer may have an atomic ratio of In:Ga:Zn=1:3:2 and the second oxide semiconductor layer may have an atomic ratio of In:Ga:Zn=2:1:3.

At this time, one of the first oxide semiconductor and the second oxide semiconductor which is closer to the gate electrode (on a channel side) preferably contains In and Ga at a proportion of In >Ga. The other which is farther from the gate electrode (on a back channel side) preferably contains In and Ga at a proportion of In≦Ga. In an oxide semiconductor, the s orbital of heavy metal mainly contributes to carrier transfer, and when the In content in the oxide semiconductor is increased, overlap of the s orbital increased is likely to be increased. Therefore, an oxide having a composition of In >Ga has higher mobility than an oxide having a composition of In≦Ga. Further, in Ga, the formation energy of oxygen vacancy is larger and thus oxygen vacancy is less likely to occur, than in In; therefore, the oxide having a composition of In≧Ga has more stable characteristics than the oxide having a composition of In >Ga. Accordingly, an oxide semiconductor containing In and Ga at a proportion of In >Ga is used on a channel side, and an oxide semiconductor containing In and Ga at a proportion of In≦Ga is used on a back channel side, so that mobility and reliability of the transistor can be further improved.

Further, when the oxide semiconductor film is formed to have a stacked structure, the first oxide semiconductor layer and the second oxide semiconductor layer may be formed using oxide semiconductor layers having different crystallinity. That is, the oxide semiconductor film may have a structure in which two of a single crystal oxide semiconductor, a polycrystalline oxide semiconductor, an amorphous oxide semiconductor, and an oxide semiconductor having crystallinity (for example, a CAAC-OS film) are combined as appropriate. When an amorphous oxide semiconductor is applied to at least either the first oxide semiconductor layer or the second oxide semiconductor layer, internal stress or external stress of the oxide semiconductor film is relieved, variation in characteristics of a transistor is reduced, and reliability of the transistor can be further improved. On the other hand, an amorphous oxide semiconductor is likely to absorb an impurity which serves as a donor, such as hydrogen, and to generate an oxygen vacancy, and thus easily becomes an n-type. Therefore, it is preferable that the oxide semiconductor having crystallinity (for example, a CAAC-OS film) be used for the oxide semiconductor on the channel side.

Before the oxide semiconductor film is formed, planarization treatment may be performed on the surface on which the oxide semiconductor film is to be formed. As the planarization treatment, polishing treatment (e.g., a CMP method), dry etching treatment, or plasma treatment can be used, though there is no particular limitation on the planarization treatment.

As plasma treatment, reverse sputtering in which an argon gas is introduced and plasma is generated can be performed. The reverse sputtering is a method in which voltage is applied to a substrate side with the use of an RF power source in an argon atmosphere and plasma is generated in the vicinity of the substrate so that a substrate surface is modified. Note that instead of argon, nitrogen, helium, oxygen or the like may be used. The reverse sputtering can remove particle substances (also referred to as particles or dust) attached to the surface on which the oxide semiconductor film is to be formed.

As the planarization treatment, polishing treatment, dry etching treatment, or plasma treatment may be performed plural times, or these treatments may be performed in combination. In the case where the treatments are combined, the order of steps is not particularly limited and may be set as appropriate depending on the roughness of the surface on which the oxide semiconductor film is to be formed.

Further, after the oxide semiconductor film is formed, the oxide semiconductor film is preferably subjected to heat treatment for reducing or removing excess hydrogen (including water and a hydroxyl group) contained in the oxide semiconductor film (dehydration or dehydrogenation).

The heat treatment is performed at higher than or equal to 250° C. and lower than or equal to 650° C., preferably higher than or equal to 450° C. and lower than or equal to 600° C. or lower than the strain point of the substrate. For example, the substrate is introduced into an electric furnace which is one of heat treatment apparatuses, and heat treatment is performed on the oxide semiconductor film at 650° C. for one hour in vacuum (under reduced pressure).

Note that the heat treatment apparatus is not limited to the electric furnace, and an apparatus for heating an object by heat conduction or heat radiation from a heater such as a resistance heater may be used. For example, an RTA apparatus such as a GRTA (gas rapid thermal annealing) apparatus or an LRTA (lamp rapid thermal annealing) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for performing heat treatment using a high-temperature gas. As the high temperature gas, an inert gas which does not react with an object by heat treatment, such as nitrogen or a rare gas like argon, is used. Note that in the case where a GRTA apparatus is used as the heat treatment apparatus, the substrate may be heated in an inert gas heated to high temperature of 650° C. to 700° C. because the heat treatment time is short.

The heat treatment enables reduction, more preferably removal of hydrogen, which is an impurity imparting n-type conductivity, in the oxide semiconductor film. Further, by this heat treatment, oxygen contained in the gate insulating film 106 can be supplied to the oxide semiconductor film. While oxygen is released from the oxide semiconductor film by the dehydration or dehydrogenation treatment, oxygen is supplied from the gate insulating film 106 to the oxide semiconductor film, whereby oxygen vacancies in the oxide semiconductor film can be filled.

In addition, after the oxide semiconductor film is heated by the heat treatment, a high-purity oxygen gas, a high-purity dinitrogen monoxide gas, or ultra dry air (the moisture amount is 20 ppm or lower (−55° C. by conversion into a dew point), preferably 1 ppm or lower, more preferably 10 ppb or lower, in the measurement with the use of a dew point meter of a cavity ring down laser spectroscopy (CRDS) system) may be introduced into the same furnace while the heating temperature is being maintained or being gradually decreased. It is preferable that water, hydrogen, or the like be not contained in the oxygen gas or the dinitrogen monoxide gas. Alternatively, the purity of the oxygen gas or the dinitrogen monoxide gas which is introduced into the heat treatment apparatus is preferably 6N or higher, further preferably 7N or higher (i.e., the impurity concentration in the oxygen gas or the dinitrogen monoxide gas is preferably 1 ppm or lower, further preferably 0.1 ppm or lower). The oxygen gas or the dinitrogen monoxide gas acts to supply oxygen that is a main component of the oxide semiconductor and that is reduced by the step of removing an impurity for the dehydration or dehydrogenation, so that the oxide semiconductor film can be a high-purity and electrically i-type (intrinsic) oxide semiconductor film.

The heat treatment for dehydration or dehydrogenation may serve as another heat treatment of a manufacturing process of the transistor 150.

Next, a conductive film is formed over the gate insulating film 106 and the semiconductor film 108 and is selectively etched, whereby the source electrode 110 and the drain electrode 112 are formed. At this stage, the transistor 150 is formed (see FIG. 5A).

The conductive film that can be used for the source electrode 110 and the drain electrode 112 is formed using a material that can withstand heat treatment performed later. For example, a metal film containing an element selected from Al, Cr, Cu, Ta, Ti, Mo, and W, or a metal nitride film containing any of the above elements as a component (a titanium nitride film, a molybdenum nitride film, or a tungsten nitride film) can be used. A metal film having a high melting point of Ti, Mo, W, or the like or a metal nitride film of any of these elements (a titanium nitride film, a molybdenum nitride film, or a tungsten nitride film) may be stacked on one of or both a lower side and an upper side of a metal film of Al, Cu, or the like.

Alternatively, the conductive film for forming the source electrode 110 and the drain electrode 112 may be formed using conductive metal oxide. Examples of the conductive metal oxide are an indium oxide (In₂O₃), a tin oxide (SnO₂), a zinc oxide (ZnO), a mixed oxide of an indium oxide and a tin oxide (In₂O₃—SnO₂, referred to as ITO), a mixed oxide of an indium oxide and a zinc oxide (In₂O₃—ZnO), and any of these metal oxide materials containing a silicon oxide.

Next, the insulating films 114 and 116 are formed over the transistor 150 (more specifically, over the semiconductor film 108, the source electrode 110, and the drain electrode 112) (see FIG. 5B).

The insulating film 114 is preferably formed using an inorganic insulating film and may be formed as a single layer or a stacked layer of any of oxide insulating films such as a silicon oxide film, a silicon oxynitride film, an aluminum oxide film, an aluminum oxynitride film, a gallium oxide film, and a hafnium oxide film. Further, over the above oxide insulating film, a single layer or a stacked layer of any of nitride insulating films such as a silicon nitride film, a silicon nitride oxide film, an aluminum nitride film, and an aluminum nitride oxide film may be formed. For example, as a stacked layer, a silicon oxide film and an aluminum oxide film can be formed in this order over the gate electrode 104 by a sputtering method.

Alternatively, a dense inorganic insulating film may be provided as the insulating film 114. For example, an aluminum oxide film is formed by a sputtering method. When the aluminum oxide film is used, by employing a high-density film (the film density is higher than or equal to 3.2 g/cm³, preferably higher than or equal to 3.6 g/cm³), the transistor 150 can have stable electric characteristics. The film density can be measured by Rutherford backscattering spectrometry (RBS) or X-ray reflection (XRR).

The aluminum oxide film that can be used as the inorganic insulating film provided over the transistor 150 has a high shielding effect (blocking effect) of preventing penetration of both oxygen and impurities such as hydrogen and moisture. Therefore, in the case where the semiconductor film 108 is the oxide semiconductor film, in and after the manufacturing process, the aluminum oxide film functions as a protective film for preventing entry of impurities such as hydrogen and moisture, which cause a change, into the oxide semiconductor film, and for preventing release of oxygen, which is a main component material of the oxide semiconductor film.

As the insulating film 116, a planarization insulating film is preferably used. The planarization insulating film can be formed using an organic material having heat resistance, such as, an acrylic resin, a polyimide resin, a benzocyclobutene-based resin, a polyamide resin, or an epoxy resin can be used. Other than these organic materials, a low-dielectric constant material (a low-k material), a siloxane-based resin, or the like can be used. Note that the planarizing insulating film may be formed by stacking a plurality of insulating films formed of any of these materials.

Next, the insulating films 114 and 116 are selectively etched to form openings reaching the source electrode 110 and the drain electrode 112 and then the openings are filled with a conductive film, whereby the connection electrodes 123 and 125 are formed (see FIG. 5C).

Note that the connection electrode 123 and 125 can be formed by a method and a material similar to those of the connection electrode 121 as described above.

Next, the first pad 120, the second pad 122, and the third pad 124 are formed on the connection electrode 121, the connection electrode 123, and the connection electrode 125, respectively (see FIG. 5D).

The first pad 120, the second pad 122, and the third pad 124 can be formed by applying a conductive material onto a desired region by a screen printing method or the like.

Through the above manufacturing steps, the semiconductor chip 100a shown in FIG. 1A can be manufactured.

Since an oxide semiconductor that is a wide bandgap semiconductor is used for the transistor of the semiconductor chip in this embodiment, the off-state current of the transistor can be sufficiently reduced. Accordingly, when the semiconductor chip described in this embodiment is used for a memory portion in a programmable switch of a programmable logic device, configuration data can be held even when supply of a power supply potential is interrupted.

Further, in this embodiment, a semiconductor chip for a programmable logic device can be manufactured independently. Thus, the manufacturing process can be simplified.

The methods and structures described in this embodiment can be combined as appropriate with any of the methods and structures described in the other embodiments.

### Embodiment 2

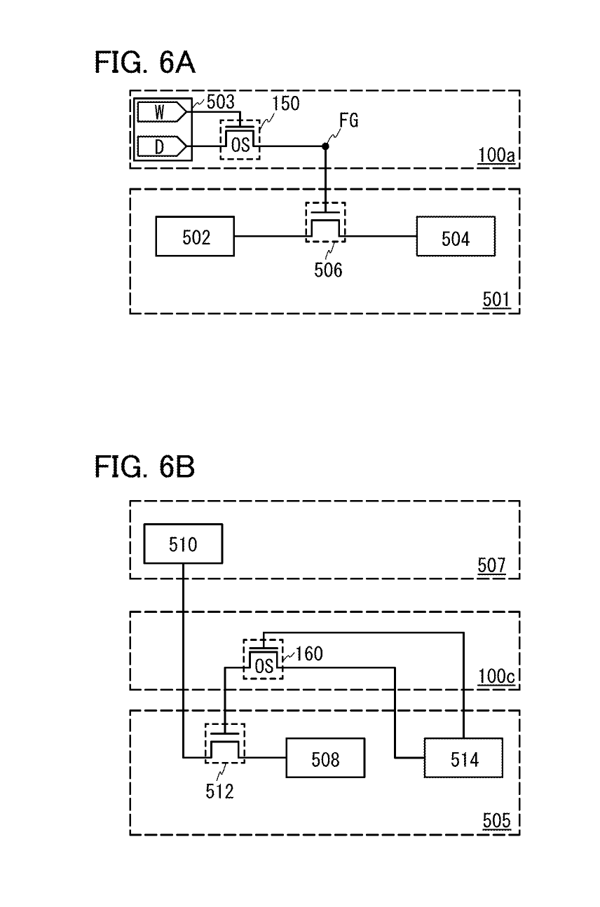

In this embodiment, examples of application of the semiconductor chip described in Embodiment 1 are described with reference to FIGS. 6A and 6B to FIGS. 8A and 8B. Note that FIGS. 6A and 6B to FIGS. 8A and 8B are block diagrams each showing a connection relation between the semiconductor chip described in Embodiment 1 and another semiconductor chip. Note that in the block diagrams shown in FIGS. 6A and 6B to FIGS. 8A and 8B, “OS” is written beside a transistor in order to indicate that the semiconductor chip described in Embodiment 1 includes a transistor including an oxide semiconductor (OS).

The block diagram shown in FIG. 6A includes a first semiconductor chip 501 including a logic circuit composed of logic blocks (logic blocks 502 and 504) and a programmable switch 506 controlling connection between the logic blocks 502 and 504, and a second semiconductor chip 100a which is stacked together with and connected to the first semiconductor chip 501. The second semiconductor chip 100a is the semiconductor chip 100a described in Embodiment 1.

A power supply control block 503 controlling a power supply potential of the semiconductor chip 100a is formed in the semiconductor chip 100a. Although the power supply control block 503 is formed in the semiconductor chip 100a in this embodiment, the structure is not limited to this example; for example, the power supply control block 503 may be formed in the first semiconductor chip 501.

Although the programmable switch 506 is formed in the first semiconductor chip 501 in the block diagram of FIG. 6A, the structure is not limited to this example; for example, the programmable switch 506 may be formed in the semiconductor chip 100a.

The logic blocks 502 and 504 are provided with at least one programmable switch 506 which controls connection between the logic block 502 and the logic block 504 in accordance with data (configuration data) electrically stored.

As described above, since the logic blocks (the logic blocks 502 and 504) included in the logic circuit are electrically connected to each other through the programmable switch 506, desired logic circuit can be formed by selective connection of the logic blocks by switching of the programmable switch 506; thus, a logic circuit having a desired logic function can be formed. Note that the logic blocks 502 and 504 may include a sequential circuit such as a flip flop or a counter circuit; for example, a shift register may be provided.

The first semiconductor chip 501 may further include a multiplier, a random access memory (RAM) block, a phase-locked loop (PLL) block, or an input/output (I/O) element. The multiplier has a function of multiplying plural pieces of data at high speed. The RAM block has a function of storing given data as a memory. The PLL block has a function of supplying a clock signal to the first semiconductor chip 501. The I/O element has a function of controlling signal passing between the first semiconductor chip 501 and an external circuit.

The semiconductor chip 100a used as the second semiconductor chip functions as a memory portion of the programmable switch 506. That is, the semiconductor chip 100a controls the programmable switch 506 in accordance with the configuration data stored in the semiconductor chip 100a functioning as a memory portion, and controls connection between the logic block 502 and the logic block 504. The semiconductor chip 100a functioning as a memory portion is electrically connected to the power supply control block 503. Specifically, the semiconductor chip 100a is electrically connected to a data line D for inputting a potential of configuration data to be stored in the semiconductor chip 100a, to a word line W for inputting a signal for controlling writing of the configuration data to the semiconductor chip 100a, and is electrically connected to the programmable switch 506 at a node storing the configuration data.

Any logic circuit can be used for any one of the logic blocks (the logic blocks 502 and 504); for example, a logic gate may be used, or a logic circuit in which logic gates are combined may be used. Although the logic circuit is composed of only two logic blocks (the logic blocks 502 and 504) in the block diagram in FIG. 6A, the number of logic blocks is not limited to this example, and three or more logic blocks may be included in the logic circuit.

The semiconductor chip 100a serving as a memory portion includes a transistor. One of a source electrode and a drain electrode of the transistor is electrically connected to the programmable switch 506. The other of the source electrode and the drain electrode of the transistor is electrically connected to the data line D. A gate electrode of the transistor is electrically connected to the word line W. A transistor having extremely small off-state current is used as the transistor. The transistor is turned off, whereby a potential corresponding to configuration data can be held in the one of the source electrode and the drain electrode electrically connected to the programmable switch 506. For example, when the state where one of a source electrode and a drain electrode is at a high potential corresponds to “1” and the state where one of a source electrode and a drain electrode is at a low potential corresponds to “0”, one-bit configuration data can be stored with the semiconductor chip 100a.

The transistor having extremely small off-state current includes, in a channel formation region, a wide bandgap semiconductor which has a wider bandgap and lower intrinsic carrier density than a silicon semiconductor. For example, as such a wide bandgap semiconductor, a compound semiconductor such as silicon carbide (SiC) or gallium nitride (GaN), an oxide semiconductor formed of a metal oxide such as an In—Ga—Zn-based oxide semiconductor, or the like can be used.

Here, the operation of writing and holding configuration data, which is shown in the block diagram in FIG. 6A is described.

First, a potential of the word line W is set to a potential at which the transistor 150 is turned on and accordingly the transistor 150 is turned on. Thus, a potential of the data line D is applied to a node (hereinafter, referred to as node FG or FG) connected to one of a source electrode and a drain electrode of the transistor 150 and the programmable switch 506. That is, a given potential is applied to a gate electrode of the programmable switch 506 (i.e., writing).

Note that an n-channel transistor is used as the programmable switch 506 in this embodiment. Note that the programmable switch 506 is not limited to this structure, and alternatively a p-channel transistor, a combination of an n-channel transistor and a p-channel transistor, or the like can be used.

After the potential of the data line D is written to the node FG, while the potential of the data line D is kept, the potential of the word line W is set to a potential at which the transistor 150 is turned off, so that the transistor 150 is turned off. The transistor 150 includes a wide bandgap semiconductor such as an oxide semiconductor and has extremely small off-state current; therefore, the given potential supplied to the node FG is held (data holding).

That is, since the potential of the gate electrode of the programmable switch 506 is held, the connection state of the programmable switch 506 is also held. Accordingly, the switching state of the programmable switch 506 can be maintained without supply of a power supply potential.

Thus, the transistor of the semiconductor chip 100a functioning as a memory portion includes a wide bandgap semiconductor such as an oxide semiconductor, which allows a sufficient reduction in off-state current of the transistor, whereby configuration data can be held for a long time even when a power supply potential is not supplied, and a switching state of the programmable switch 506 can be maintained. Accordingly, a driving method (so called normally-off driving method) in which supply of a power supply potential to the semiconductor chip 100a and the first semiconductor chip 501 is temporarily interrupted and a power supply potential is supplied to a logic block which requires power only when needed can be used. Since configuration data is held, writing of configuration data after power on can be omitted, so that the start time of the logic block included in a logic circuit can be shortened. Further, power consumption can be reduced by the normally-off driving method.

Further, a potential corresponding to configuration data is supplied to the node FG through the transistor 150 of the semiconductor chip 100a, whereby the data can be written. As compared to the case where a floating gate is used for a memory portion of a programmable switch and configuration data is written by injection of electrons, a potential and time required for writing data can be greatly reduced. Moreover, a problem in that a gate insulating film of a floating gate deteriorates because of tunneling current generated in the injection of electrons does not occur; accordingly, the number of configuration data rewrite cycles can be increased.

Next, a structure different from the block diagram shown in FIG. 6A is described with reference to FIG. 6B.

The block diagram shown in FIG. 6B includes a first semiconductor chip 505 including a logic circuit composed of a first logic block 508, a programmable switch 512 which is connected to the first logic block 508, a second semiconductor chip which is stacked together with and connected to the first semiconductor chip 505, and a third semiconductor chip 507 including a logic circuit composed of a second logic block 510. The third semiconductor chip 507 is connected to and stacked over the first semiconductor chip 505 with the second semiconductor chip provided therebetween. The second semiconductor chip is the semiconductor chip 100c described in Embodiment 1.

Further, the first semiconductor chip 505 includes a power supply control block 514 controlling a power supply potential of the second semiconductor chip, i.e., the semiconductor chip 100c. Although the power supply control block 514 is formed in the first semiconductor chip 505 in this embodiment, the structure is not limited to this example; for example, the power supply control block 514 may be formed in the semiconductor chip 100c or the third semiconductor chip 507.

Although the programmable switch 512 is formed in the first semiconductor chip 505 in the block diagram of FIG. 6B, the structure is not limited to this example; for example, the programmable switch 512 may be formed in the semiconductor chip 100c or the third semiconductor chip 507.

The first logic block 508 and the second logic block 510 are provided with at least one programmable switch 512 which control connection between the first logic block 508 and the second logic block 510 in accordance with data (configuration data) electrically stored in the semiconductor chip.

Since such logic blocks (the first logic block 508 and the second logic block 510) included in a logic circuit are electrically connected to each other through the programmable switch 512, desired logic circuit can be formed by selective connection between the first logic block 508 and the second logic block 510 by switching of the programmable switch 512; thus, a logic circuit having a desired logic function can be formed. Note that the first logic block 508 and the second logic block 510 may include a sequential circuit such as a flip flop or a counter circuit; for example, a shift register may be provided.

The first semiconductor chip 505 and the third semiconductor chip 507 may further include a multiplier, a random access memory (RAM) block, a phase-locked loop (PLL) block, or an input/output (I/O) element.

The semiconductor chip 100c serves as a memory portion of the programmable switch 512. That is, the semiconductor chip 100c controls the programmable switch 512 in accordance with the configuration data stored in the semiconductor chip 100c serving as a memory portion, and controls connection between the first logic block 508 and the second logic block 510. The semiconductor chip 100c serving as a memory portion is electrically connected to the power supply control block 514 which input a potential of configuration data to be stored in the semiconductor chip 100c and input a signal for controlling writing of the configuration data. The semiconductor chip 100c is electrically connected to the programmable switch 512 at a node storing the configuration data.

Any logic circuit can be used as the logic blocks 502 and 504; for example, a logic gate may be used, or a logic circuit in which logic gates are combined may be used. Although the logic circuit formed by the logic blocks 502 and 504 is composed of only two logic blocks in the block diagram in FIG. 6B, the number of logic blocks is not limited to this example; for example, three or more logic blocks may be included in the first semiconductor chip 505 and the third semiconductor chip 507.

The semiconductor chip 100c serving as a memory portion includes a transistor. One of a source electrode and a drain electrode of the transistor is electrically connected to the programmable switch 512. The other of the source electrode and the drain electrode of the transistor is electrically connected to the power supply control block 514. A gate electrode of the transistor is electrically connected to the power supply control block 514. A transistor having extremely small off-state current is used as the transistor. The transistor is turned off, whereby a potential corresponding to configuration data can be held in the one of the source electrode and the drain electrode electrically connected to the programmable switch 512.

Note that the description of the block diagram shown in FIG. 6A is referred to for the operation of writing and holding configuration data, which is shown in the block diagram in FIG. 6B.

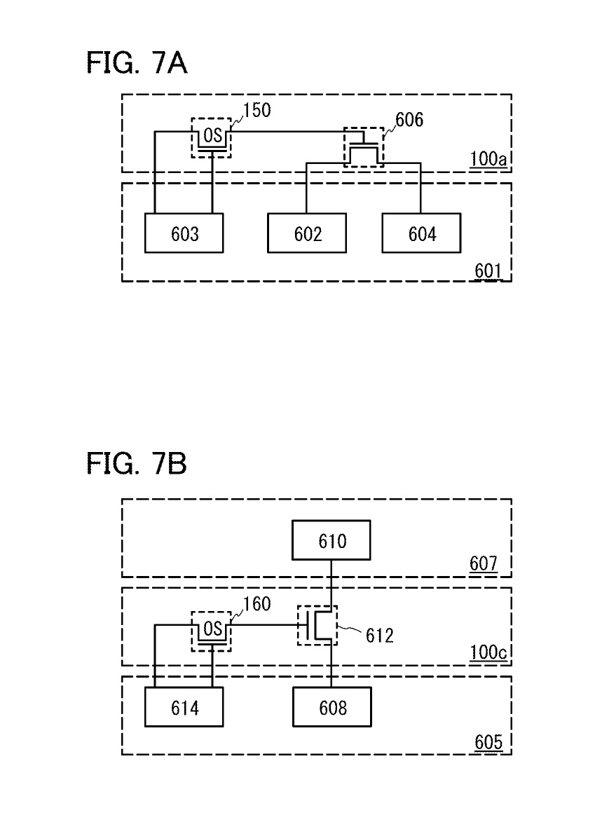

Next, a structure different from the block diagram shown in FIG. 6A is described with reference to FIG. 7A.

The block diagram shown in FIG. 7A includes a first semiconductor chip 601 including a logic circuit composed of logic blocks (logic blocks 602 and 604) and a power supply control block 603 controlling a power supply potential of a second semiconductor chip, and the second semiconductor chip which is stacked over and connected to the first semiconductor chip 601. The second semiconductor chip is the semiconductor chip 100a in Embodiment 1.

Further, a programmable switch 606 controlling connection between the logic blocks 602 and 604 is formed in the semiconductor chip 100a. Further, the power supply control block 603 controlling a power potential of the semiconductor chip 100a is formed in the first semiconductor chip 601.

As described above, the programmable switch and the power supply control block can be provided in the most suitable semiconductor chip by a practitioner as appropriate. Note that the block diagram shown in FIG. 6A can be referred to for the other components.

Next, a structure different from the block diagram shown in FIG. 6B is described with reference to FIG. 7B.

The block diagram shown in FIG. 7B includes a first semiconductor chip 605 including a logic circuit composed of a first logic block 608 and a power supply control block 614 controlling a power supply potential, a second semiconductor chip which is stacked over and connected to the first semiconductor chip 605, and a third semiconductor chip 607 which includes a logic circuit composed of a second logic block 610. The third semiconductor chip 607 is connected to and stacked over the first semiconductor chip 605 with the second semiconductor chip provided therebetween. The second semiconductor chip is the semiconductor chip 100c described in Embodiment 1.

Further, a programmable switch 612 controlling connection between the first logic block 608 and the second logic block 610 is formed in the semiconductor chip 100c.

As described above, the programmable switch and the power supply control block can be provided in the most suitable semiconductor chip by a practitioner as appropriate. Note that the block diagrams shown in FIGS. 6A and 6B can be referred to for the other components

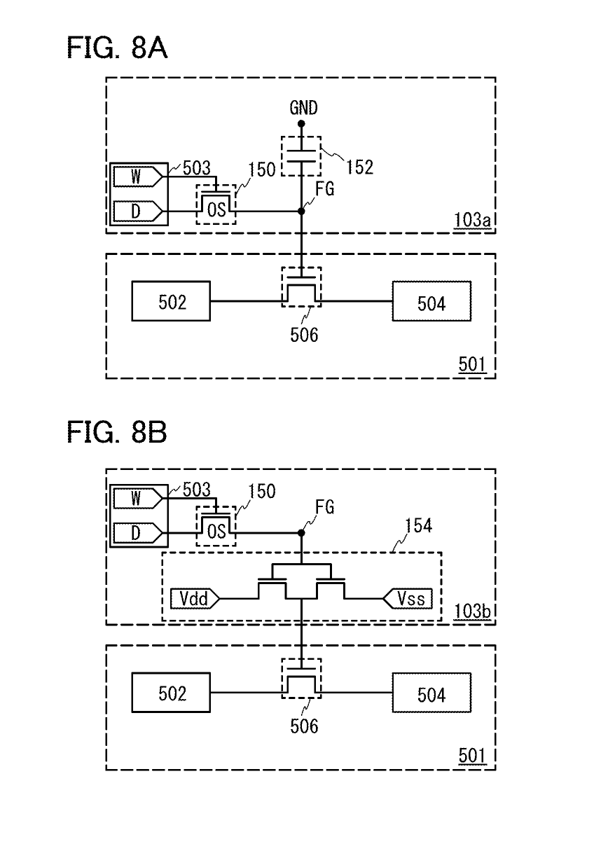

FIG. 8A shows a modification example of the block diagram shown in FIG. 6A. The structure shown in FIG. 8A includes a semiconductor chip 103a in which a capacitor 152 is added to the semiconductor chip 100a shown in FIG. 6A. One electrode of the capacitor 152 is electrically connected to the node FG, and the other thereof is electrically connected to the ground potential line (GND). Such a structure that the capacitor 152 holding a potential of the node FG is included may be used.

FIG. 8B shows a modification example of the block diagram shown in FIG. 8A. The structure shown in FIG. 8B includes a semiconductor chip 103b in which a buffer circuit 154 is added to the semiconductor chip 100a shown in FIG. 8A.

The buffer circuit 154 includes two transistors (a first transistor and a second transistor), preferably a combination of transistors having different polarities. Gate electrodes of the two transistors are connected to each other and electrically connected to the node FG. One of a source electrode and a drain electrode of the first transistor is connected to a power supply line to which high potential power supply (Vdd) is applied, and the other thereof is connected to one of a source electrode and a drain electrode of the second transistor. The other of the source electrode and the drain electrode of the second transistor is connected to a power supply line to which low potential power supply (Vss) is applied.

As described, since the buffer circuit 154 is added, a potential applied to the programmable switch 506 can be adjusted. Although the semiconductor chip 103b includes the buffer circuit 154 in the block diagram shown in FIG. 8B, the structure is not limited to this example. For example, the first semiconductor chip 501 may include the buffer circuit 154, and alternatively another semiconductor chip may include the buffer circuit 154.

In addition, a protection circuit for protection from electrostatic discharge (ESD) or the like may be provided for each chip in the block diagrams shown in FIGS. 6A and 6B to FIGS. 8A and 8B.

As described above, in this embodiment, a logic block included in a logic circuit and a semiconductor chip having a memory function are formed in different chips and connected to each other. Accordingly, a semiconductor chip in which a logic circuit composed of a logic block is formed and a semiconductor chip having a memory function can be formed over different substrates and thus manufacturing cost can be reduced.

The methods and structures described in this embodiment can be combined as appropriate with any of the methods and structures described in the other embodiments.

### Embodiment 3

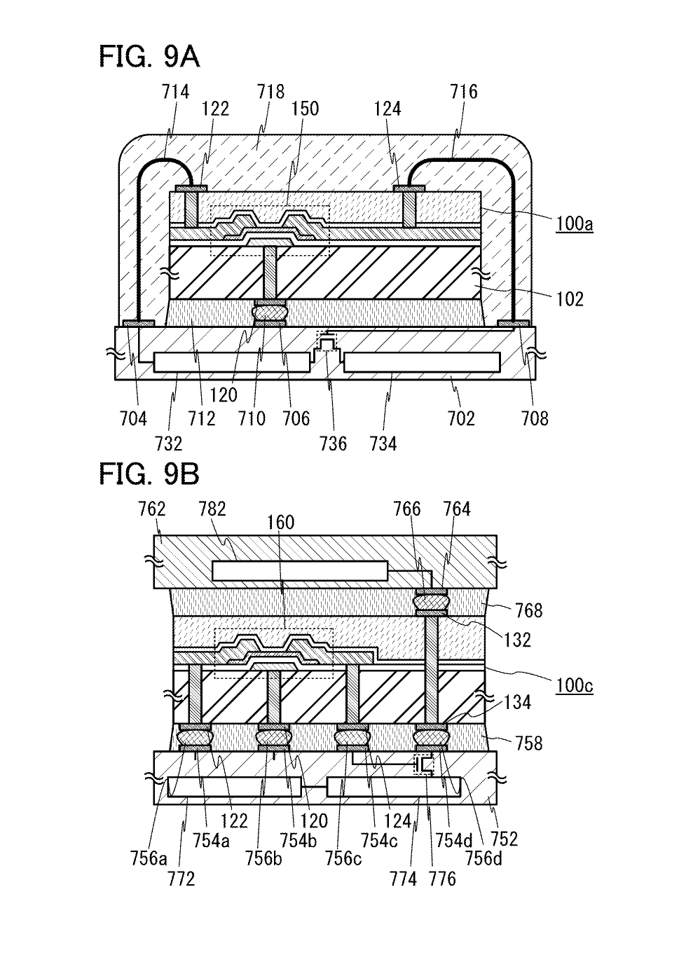

In this embodiment, a semiconductor device in which the semiconductor chip which is one embodiment of the present invention and described in Embodiment 1 and another semiconductor chip are stacked is described with reference to FIGS. 9A and 9B. In order to avoid complexity of the drawing, a circuit included in another semiconductor chip is illustrated as a block diagram in FIGS. 9A and 9B.

The semiconductor device shown in FIG. 9A has a structure in which the semiconductor chip 100a described in Embodiment 1 is stacked over and connected to a first semiconductor chip 702.

The semiconductor chip 100a includes the first pad 120 electrically connected to the gate electrode of the transistor 150, the second pad 122 electrically connected to the source electrode of the transistor 150, and the third pad 124 electrically connected to the drain electrode of the transistor 150. The first semiconductor chip 702 includes a fourth pad 704, a fifth pad 706, and a sixth pad 708 formed on the first semiconductor chip 702.

The first pad 120 of the semiconductor chip 100a is electrically connected to the fifth pad 706 formed on the first semiconductor chip 702 through a solder bump 710. The second pad 122 of the semiconductor chip 100a is electrically connected to the fourth pad 704 formed on the first semiconductor chip 702 through a bonding wiring 714. The third pad 124 of the semiconductor chip 100a is electrically connected to the sixth pad 708 formed on the first semiconductor chip 702 through a bonding wiring 716.

A connection portion between the first semiconductor chip 702 and the semiconductor chip 100a is filled with an under-fill material 712. As the under-fill material 712, a resin material such as an epoxy resin can be used.

A sealing resin 718 covering the first semiconductor chip 702 and the semiconductor chip 100a is formed. Examples of the sealing resin 718 include an epoxy resin, an acrylic resin, a silicone resin, an urethane resin, a polyimide resin, and a polyethylene resin, which have high insulating properties.

Since the bonding wirings 714 and 716 need to have conductivity; for example, a material such as aluminum, gold, silver, copper, platinum, and iron can be used.

Note that the first semiconductor chip 702 includes a logic circuit composed of logic blocks (logic blocks 732 and 734) and a programmable switch 736 controlling connection between the logic blocks.

The first semiconductor chip 702 and the semiconductor chip 100a are bonded to each other as described above and accordingly configuration data applied to the programmable switch 736 can be held in the semiconductor chip 100a.

Further, since the first semiconductor chip 702 and the semiconductor chip 100a can be formed independently of each other, manufacturing cost can be reduced.

Next, the semiconductor device illustrated in FIG. 9B will be described.

The semiconductor device shown in FIG. 9B includes a first semiconductor chip 752, the semiconductor chip 100c described in Embodiment 1 as a second semiconductor chip, and a third semiconductor chip 762. The third semiconductor chip 762 is stacked together with and connected to the first semiconductor chip 752 with the semiconductor chip 100c provided therebetween.

The semiconductor chip 100c includes the first pad 120 electrically connected to a gate electrode of the transistor 160, the second pad 122 electrically connected to a source electrode of the transistor 160, the third pad 124 electrically connected to a drain electrode of the transistor 160, the fourth pad 132 electrically connected to one end of a through electrode which passes through the semiconductor chip 100c, and the fifth pad 134 electrically connected to the other end of the through electrode which passes through the semiconductor chip 100c.

The first semiconductor chip 752 includes a sixth pad 754a, a seventh pad 754b, an eighth pad 754c, and a ninth pad 754d which are formed on the first semiconductor chip 752. The third semiconductor chip 762 includes a tenth pad 764 formed on the third semiconductor chip 762.

The first pad 120 of the semiconductor chip 100c is electrically connected to the seventh pad 754b formed on the first semiconductor chip 752 through a solder bump 756b. The second pad 122 of the semiconductor chip 100c is electrically connected to the sixth pad 754a formed on the first semiconductor chip 752 through a solder bump 756a. The third pad 124 of the semiconductor chip 100c is electrically connected to the eighth pad 754c formed on the first semiconductor chip 752 through a solder bump 756c. The fifth pad 134 of the semiconductor chip 100c is electrically connected to the ninth pad 754d formed on the first semiconductor chip 752 through a solder bump 756d. The fourth pad 132 of the first semiconductor chip 752 is electrically connected to the tenth pad 764 formed on the third semiconductor chip 762 through a solder bump 766.

A connection portion between the semiconductor chip 100c and the first semiconductor chip 752 is filled with an under-fill material 758. A connection portion between the semiconductor chip 100c and the third semiconductor chip 762 is filled with an under-fill material 768. As the under-fill materials 758 and 768, a material similar to the above-described material of the under-fill 712 can be used.

Note that the first semiconductor chip 752 includes a control block 772, a power supply control block 774 connected to the control block 772, and a switch 776 electrically connected to the power supply control block 774. In addition, the third semiconductor chip 762 includes a logic circuit composed of a logic block 782.

As described above, the first semiconductor chip 752 and the third semiconductor chip 762 are bonded to each other with the semiconductor chip 100c sandwiched therebetween and accordingly data applied to the switch 776 can be held in the semiconductor chip 100c. Since the switch 776 is connected to the logic block formed in the third semiconductor chip 762, the switch 776 can also control power supplied to the logic block.

Further, since the first semiconductor chip 752, the semiconductor chip 100c, and the third semiconductor chip 762 can be manufactured independently of one another, manufacturing cost can be reduced.

The methods and structures described in this embodiment can be combined as appropriate with any of the methods and structures described in the other embodiments.

### Embodiment 4

A semiconductor device according to one embodiment of the present invention can realize an electronic device with low power consumption. In particular, in the case of a portable electronic device which has difficulty in continuously receiving power, an advantage in increasing the continuous duty period can be obtained when a semiconductor device with low power consumption according to one embodiment of the present invention is added as a component of the device.

The semiconductor device according to one embodiment of the present invention can be used for display devices, laptops, or image reproducing devices provided with recording media (typically, devices which reproduce the content of recording media and have displays for displaying the reproduced images such as digital versatile discs (DVDs)). Other than the above, as an electronic device which can use the semiconductor device according to one embodiment of the present invention, mobile phones, game machines including portable game machines, portable information terminals, e-book readers, video cameras, digital still cameras, goggle-type displays (head mounted displays), navigation systems, audio reproducing devices (e.g., car audio systems and digital audio players), copiers, facsimiles, printers, multifunction printers, automated teller machines (ATM), vending machines, and the like can be given.

The case where the semiconductor device according to one embodiment of the present invention is applied to electronic devices such as a mobile phone, a smartphone, and an e-book reader will be described

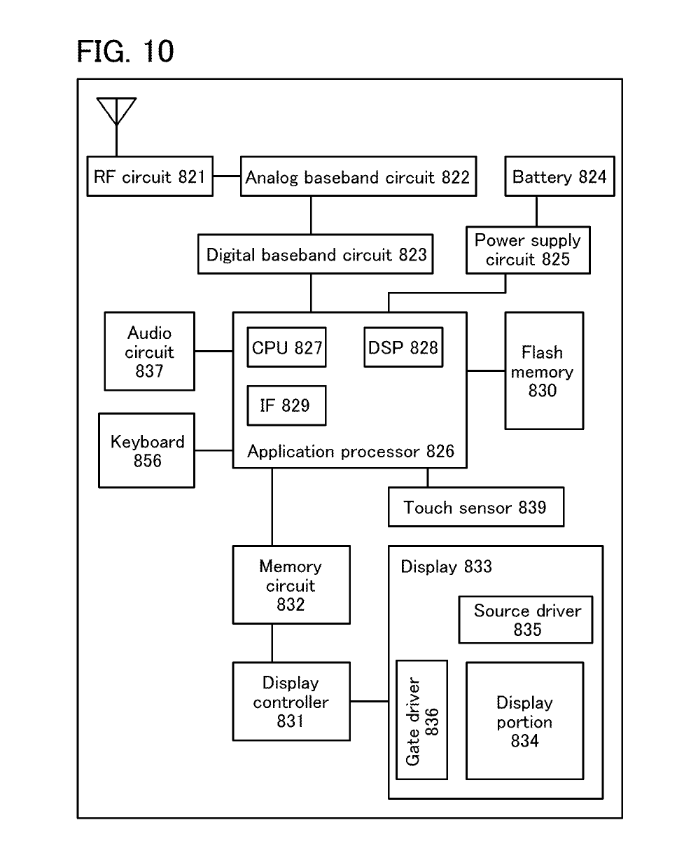

FIG. 10 is a block diagram of a portable electronic device. The portable electronic device illustrated in FIG. 10 includes an RF circuit 821, an analog baseband circuit 822, a digital baseband circuit 823, a battery 824, a power supply circuit 825, an application processor 826, a flash memory 830, a display controller 831, a memory circuit 832, a display 833, a touch sensor 839, an audio circuit 837, a keyboard 838, and the like. The display 833 includes a display portion 834, a source driver 835, and a gate driver 836. The application processor 826 includes a CPU 827, a digital signal processor (DSP) 828, and an interface 829. For example, when the semiconductor device described in any of the above embodiments is used for any or all of the RF circuit 821, the analog baseband circuit 822, the memory circuit 832, the application processor 826, the display controller 831, and the audio circuit 837, power consumption can be reduced.

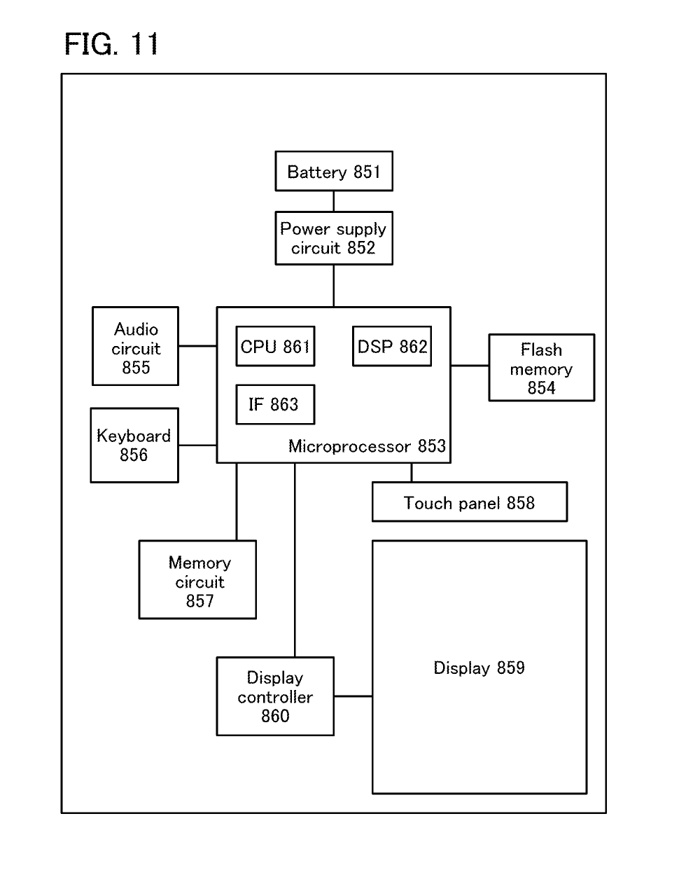

FIG. 11 is a block diagram of an e-book reader. The e-book reader includes a battery 851, a power supply circuit 852, a microprocessor 853, a flash memory 854, an audio circuit 855, a keyboard 856, a memory circuit 857, a touch panel 858, a display 859, and a display controller 860. The microprocessor 853 includes a CPU 861, a DSP 862, and an interface (IF) 863. For example, when the programmable logic device described in any of the above embodiments is used for any or all of the audio circuit 855, the memory circuit 857, the microprocessor 853, and the display controller 860, power consumption can be reduced.

The methods and structures described in this embodiment can be combined as appropriate with any of the methods and structures described in the other embodiments. This application is based on Japanese Patent Application serial No. 2012-108283 filed with Japan Patent Office on May 10, 2012, the entire contents of which are hereby incorporated by reference.

What is claimed is:

1. A semiconductor device comprising:
a first semiconductor chip comprising a transistor;
at least one second semiconductor chip comprising a first circuit and a second circuit; and
a programmable switch configured to control connection between the first circuit and the second circuit,
wherein a state of the programmable switch is controlled by a potential of one of a source electrode and a drain electrode of the transistor.

2. A semiconductor device comprising:
a first semiconductor chip comprising a first transistor;
at least one second semiconductor chip comprising a first circuit and a second circuit; and
a second transistor comprising a source electrode electrically connected to the first circuit, a drain electrode electrically connected to the second circuit, and a gate electrode electrically connected to one of a source electrode and a drain electrode of the first transistor.

3. A semiconductor device comprising:
a first semiconductor chip comprising a first transistor;
at least one second semiconductor chip comprising a first circuit and a second circuit; and
a second transistor comprising a source electrode electrically connected to the first circuit, a drain electrode electrically connected to the second circuit, and a gate electrode electrically connected to one of a source electrode and a drain electrode of the first transistor,
wherein a channel formation region of the first transistor comprises an oxide semiconductor material.

4. The semiconductor device according to claim 1,
wherein a first semiconductor layer in the first semiconductor chip is formed from a first semiconductor material,
wherein a second semiconductor layer in the at least one second semiconductor chip is formed from a second semiconductor material, and
wherein the first semiconductor material and the second semiconductor material are different from each other.

5. The semiconductor device according to claim 2,
wherein a first semiconductor layer in the first semiconductor chip is formed from a first semiconductor material,
wherein a second semiconductor layer in the at least one second semiconductor chip is formed from a second semiconductor material, and
wherein the first semiconductor material and the second semiconductor material are different from each other.

6. The semiconductor device according to claim 3,
wherein a first semiconductor layer in the first semiconductor chip is formed from the oxide semiconductor material,
wherein a second semiconductor layer in the at least one second semiconductor chip is formed from a second semiconductor material, and
wherein the oxide semiconductor material and the second semiconductor material are different from each other.

7. The semiconductor device according to claim 1,
wherein a first semiconductor layer in the first semiconductor chip is formed from an oxide semiconductor material, and
wherein a second semiconductor layer in the at least one second semiconductor chip is formed from a silicon-based semiconductor material.

8. The semiconductor device according to claim 2,
wherein a first semiconductor layer in the first semiconductor chip is formed from an oxide semiconductor material, and
wherein a second semiconductor layer in the at least one second semiconductor chip is formed from a silicon-based semiconductor material.

9. The semiconductor device according to claim 3,
wherein a first semiconductor layer in the first semiconductor chip is formed from the oxide semiconductor material, and
wherein a second semiconductor layer in the at least one second semiconductor chip is formed from a silicon-based semiconductor material.

10. The semiconductor device according to claim 1, further comprising a power supply control block,
wherein the power supply control block is configured to control the state of the programmable switch through the transistor, and
wherein the power supply control block is formed in the at least one second semiconductor chip.

11. The semiconductor device according to claim 2, further comprising a power supply control block,
wherein the power supply control block is configured to control a state of the second transistor through the first transistor, and
wherein the power supply control block is formed in the at least one second semiconductor chip.

12. The semiconductor device according to claim 3, further comprising a power supply control block,
wherein the power supply control block is configured to control a state of the second transistor through the first transistor, and
wherein the power supply control block is formed in the at least one second semiconductor chip.

13. The semiconductor device according to claim 1,
wherein the first circuit and the second circuit are logic blocks.

14. The semiconductor device according to claim 2,
wherein the first circuit and the second circuit are logic blocks.

15. The semiconductor device according to claim 3,
wherein the first circuit and the second circuit are logic blocks.

16. The semiconductor device according to claim 1,
wherein the first circuit is a logic block and the second circuit is a power supply control block.

17. The semiconductor device according to claim 2,
wherein the first circuit is a logic block and the second circuit is a power supply control block.

18. The semiconductor device according to claim 3,
wherein the first circuit is a logic block and the second circuit is a power supply control block.

19. An electronic device comprising the semiconductor device according to claim 1.

20. An electronic device comprising the semiconductor device according to claim 2.

21. An electronic device comprising the semiconductor device according to claim 3.
